(19) United States
(12) Patent Application Publication
(10) Pub. No.: US 2013/0127775 A1
(43) Pub. Date: May 23, 2013

(54) Single-Layer Touch Sensor with Crossovers

(71) Applicants: Esat Yilmaz, Santa Cruz, CA (US); Jalil Shaikh, Fremont, CA (US); Isfandyar Qazi, Fremont, CA (US); Michael Thomas Morrione, San Jose, CA (US); David Brent Guard, Hampshire (GB)

(72) Inventors: Esat Yilmaz, Santa Cruz, CA (US); Jalil Shaikh, Fremont, CA (US); Isfandyar Qazi, Fremont, CA (US); Michael Thomas Morrione, San Jose, CA (US); David Brent Guard, Hampshire (GB)

(21) Appl. No.: 13/363,887

(22) Filed: Feb. 1, 2012

Related U.S. Application Data
(60) Provisional application No. 61/563,007, filed on Nov. 22, 2011.

(51) Int. Cl. G06F 3/044; H03K 17/975

(52) U.S. Cl. 345/174; 200/600

(57) ABSTRACT

In one embodiment, an apparatus includes drive or sense electrodes of a touch sensor. Each of the electrodes are made of a conductive mesh of lines of conductive material. The apparatus also includes one or more conductive crossovers that each couple two of the drive electrodes to each other or couple two of the sense electrodes to each other. At least a portion of each of the conductive crossovers is disposed on a plane different than a plane of the drive or sense electrodes.

### RELATED APPLICATION

This application claims the benefit, under 35 U.S.C. §119(e), of U.S. Provisional Patent Application No. 61/563,007, filed 22 Nov. 2011, which is incorporated herein by reference.

### TECHNICAL FIELD

This disclosure generally relates to touch sensors.

### BACKGROUND

A touch position sensor may detect the presence and location of a touch or the proximity of an object (such as a user's finger or a stylus) within a touch-sensitive area of the touch sensor overlaid on a display screen, for example. In a touch-sensitive display application, the touch position sensor may enable a user to interact directly with what is displayed on the screen, rather than indirectly with a mouse or touch pad. A touch sensor may be attached to or provided as part of a desktop computer, laptop computer, tablet computer, personal digital assistant (PDA), smartphone, satellite navigation device, portable media player, portable game console, kiosk computer, point-of-sale device, or other suitable device. A control panel on a household or other appliance may include a touch sensor.

There are a number of different types of touch position sensors, such as (for example) resistive touch screens, surface acoustic wave touch screens, and capacitive touch screens. Herein, reference to a touch sensor may encompass a touch screen, and vice versa, where appropriate. When an object touches or comes within proximity of the surface of the capacitive touch screen, a change in capacitance may occur within the touch screen at the location of the touch or proximity. A controller may process the change in capacitance to determine its position on the touch screen.

### BRIEF DESCRIPTION OF THE DRAWINGS

FIG. 1 illustrates an example touch sensor with an example controller.

FIGS. 2A-C illustrate example mesh patterns.

FIGS. 3A-B illustrate plan views of example electrode patterns with crossovers.

FIG. 4 illustrates an example cross-sectional view of an example crossover.

### DESCRIPTION OF EXAMPLE EMBODIMENTS

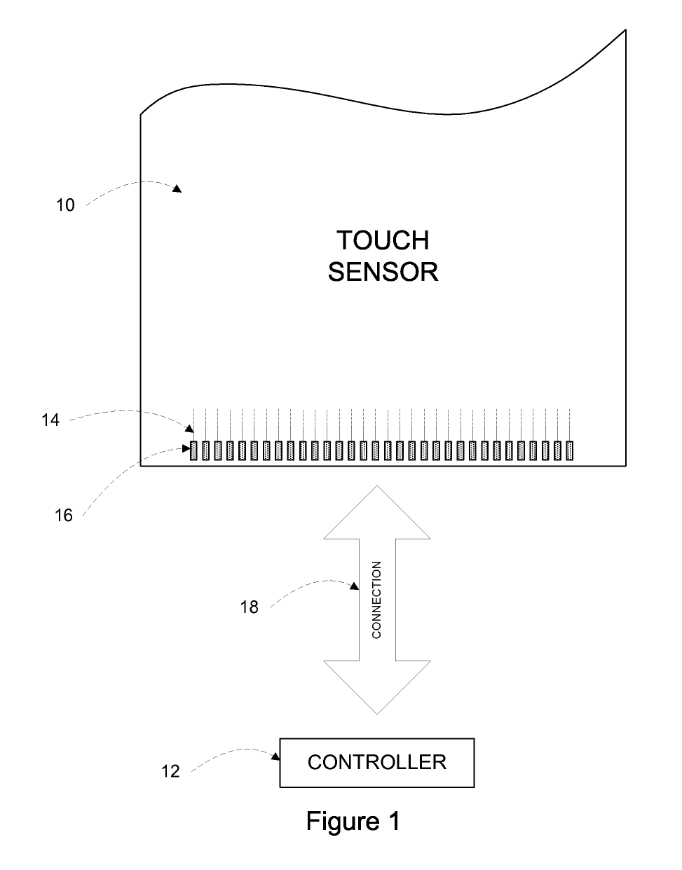

FIG. 1 illustrates an example touch sensor 10 with an example controller 12. Herein, reference to a touch sensor may encompass a touch screen, and vice versa, where appropriate. Touch sensor 10 and controller 12 may detect the presence and location of a touch or the proximity of an object within a touch-sensitive area of touch sensor 10. Herein, reference to a touch sensor may encompass both the touch sensor and its controller, where appropriate. Similarly, reference to a controller may encompass both the controller and its touch sensor, where appropriate. Touch sensor 10 may include one or more touch-sensitive areas, where appropriate. Touch sensor 10 may include an array of drive and sense electrodes (or an array of electrodes of a single type) disposed on one or more substrates, which may be made of a dielectric material. Herein, reference to a touch sensor may encompass both the electrodes of the touch sensor and the substrate(s) that they are disposed on, where appropriate. Alternatively, where appropriate, reference to a touch sensor may encompass the electrodes of the touch sensor, but not the substrate(s) that they are disposed on.

An electrode (whether a drive electrode or a sense electrode) may be an area of conductive material forming a shape, such as for example a disc, square, rectangle, other suitable shape, or suitable combination of these. In particular embodiments, the conductive material of an electrode may occupy approximately 100% of the area of its shape. As an example and not by way of limitation, an electrode may be made of indium tin oxide (ITO) and the ITO of the electrode may occupy approximately 100% of the area of its shape, where appropriate. In particular embodiments, the conductive material of an electrode may occupy approximately 5% of the area of its shape, as described below. Although this disclosure describes or illustrates particular electrodes made of particular conductive material forming particular shapes with particular fills having particular patterns, this disclosure contemplates any suitable electrodes made of any suitable conductive material forming any suitable shapes with any suitable fills having any suitable patterns. Where appropriate, the shapes of the electrodes (or other elements) of a touch sensor may constitute in whole or in part one or more macro-features of the touch sensor. One or more characteristics of the implementation of those shapes (such as, for example, the conductive materials, fills, or patterns within the shapes) may constitute in whole or in part one or more micro-features of the touch sensor. One or more macro-features of a touch sensor may determine one or more characteristics of its functionality, and one or more micro-features of the touch sensor may determine one or more optical features of the touch sensor, such as transmittance, refraction, or reflection.

One or more portions of the substrate of touch sensor 10 may be made of polyethylene terephthalate (PET) or another suitable material. In particular embodiments, the substrate may be made using substantially flexible material, such that structural integrity of the substrate is maintained after significant deformation. As an example and not by way of limitation, a substrate made of substantially flexible material may enable one or more portions of the flexible substrate to wrap around an edge of a surface. This disclosure contemplates any suitable substrate with any suitable portions made of any suitable material. In particular embodiments, the drive or sense electrodes in touch sensor 10 may be made of ITO in whole or in part. In particular embodiments, the drive or sense electrodes in touch sensor 10 may be made of fine lines of metal or other conductive material.

A mechanical stack may contain the substrate (or multiple substrates) and the conductive material forming the drive or sense electrodes of touch sensor 10. As an example and not by way of limitation, the mechanical stack may include a first layer of optically clear adhesive (OCA) beneath a cover panel. The cover panel may be clear and made of a resilient material suitable for repeated touching, such as for example glass, polycarbonate, or poly(methyl methacrylate) (PMMA). This disclosure contemplates any suitable cover panel made of any suitable material. The first layer of OCA may be disposed between the cover panel and the substrate with the conductive material forming the drive or sense electrodes. The mechanical stack may also include a second layer of OCA and a dielectric layer (which may be made of PET or another suitable material, similar to the substrate with the conductive material forming the drive or sense electrodes) or a thin coating of a dielectric material. The second layer of OCA may be disposed between the substrate with the conductive material making up the drive or sense electrodes and the dielectric layer, and the dielectric layer may be disposed between the second layer of OCA and an air gap to a display of a device including touch sensor 10 and controller 12. As an example and not by way of limitation, the cover panel may have a thickness of approximately 1 millimeter (mm); the first layer of OCA may have a thickness of approximately 0.05 mm; the substrate with the conductive material forming the drive or sense electrodes may have a thickness of approximately 0.05 mm; the second layer of OCA may have a thickness of approximately 0.05 mm; and the dielectric layer may have a thickness of approximately 0.05 mm. Although this disclosure describes a particular mechanical stack with a particular number of particular layers made of particular materials and having particular thicknesses, this disclosure contemplates any suitable mechanical stack with any suitable number of any suitable layers made of any suitable materials and having any suitable thicknesses. As an example and not by way of limitation, in particular embodiments, a layer of adhesive or dielectric may replace the dielectric layer, second layer of OCA, and air gap described above, with there being no air gap to the display.

Touch sensor 10 may implement a capacitive form of touch sensing. In a mutual-capacitance implementation, touch sensor 10 may include an array of drive and sense electrodes forming an array of capacitive nodes. A drive electrode and a sense electrode may form a capacitive node. The drive and sense electrodes forming the capacitive node may come near each other, but not make electrical contact with each other. Instead, the drive and sense electrodes may be capacitively coupled to each other across a space between them. A pulsed or alternating voltage applied to the drive electrode (by controller 12) may induce a charge on the sense electrode, and the amount of charge induced may be susceptible to external influence (such as a touch or the proximity of an object). When an object touches or comes within proximity of the capacitive node, a change in capacitance may occur at the capacitive node and controller 12 may measure the change in capacitance. By measuring changes in capacitance throughout the array, controller 12 may determine the position of the touch or proximity within the touch-sensitive area(s) of touch sensor 10.

In a self-capacitance implementation, touch sensor 10 may include an array of electrodes of a single type that may each form a capacitive node. When an object touches or comes within proximity of the capacitive node, a change in self-capacitance may occur at the capacitive node and controller 12 may measure the change in capacitance, for example, as a change in the amount of charge needed to raise the voltage at the capacitive node by a pre-determined amount. As with a mutual-capacitance implementation, by measuring changes in capacitance throughout the array, controller 12 may determine the position of the touch or proximity within the touch-sensitive area(s) of touch sensor 10. This disclosure contemplates any suitable form of capacitive touch sensing, where appropriate.

In particular embodiments, one or more drive electrodes may together form a drive line running horizontally or vertically or in any suitable orientation. Similarly, one or more sense electrodes may together form a sense line running horizontally or vertically or in any suitable orientation. In particular embodiments, drive lines may run substantially perpendicular to sense lines. Herein, reference to a drive line may encompass one or more drive electrodes making up the drive line, and vice versa, where appropriate. Similarly, reference to a sense line may encompass one or more sense electrodes making up the sense line, and vice versa, where appropriate.

Touch sensor 10 may have drive and sense electrodes disposed in a pattern on one side of a single substrate. In such a configuration, a pair of drive and sense electrodes capacitively coupled to each other across a space between them may form a capacitive node. For a self-capacitance implementation, electrodes of only a single type may be disposed in a pattern on a single substrate. In addition or as an alternative to having drive and sense electrodes disposed in a pattern on one side of a single substrate, touch sensor 10 may have drive electrodes disposed in a pattern on one side of a substrate and sense electrodes disposed in a pattern on another side of the substrate. Moreover, touch sensor 10 may have drive electrodes disposed in a pattern on one side of one substrate and sense electrodes disposed in a pattern on one side of another substrate. In such configurations, an intersection of a drive electrode and a sense electrode may form a capacitive node. Such an intersection may be a location where the drive electrode and the sense electrode “cross” or come nearest each other in their respective planes. The drive and sense electrodes do not make electrical contact with each other—instead they are capacitively coupled to each other across a dielectric at the intersection. Although this disclosure describes particular configurations of particular electrodes forming particular nodes, this disclosure contemplates any suitable configuration of any suitable electrodes forming any suitable nodes. Moreover, this disclosure contemplates any suitable electrodes disposed on any suitable number of any suitable substrates in any suitable patterns.

As described above, a change in capacitance at a capacitive node of touch sensor 10 may indicate a touch or proximity input at the position of the capacitive node. Controller 12 may detect and process the change in capacitance to determine the presence and location of the touch or proximity input. Controller 12 may then communicate information about the touch or proximity input to one or more other components (such one or more central processing units (CPUs) or digital signal processors (DSPs)) of a device that includes touch sensor 10 and controller 12, which may respond to the touch or proximity input by initiating a function of the device (or an application running on the device) associated with it. Although this disclosure describes a particular controller having particular functionality with respect to a particular device and a particular touch sensor, this disclosure contemplates any suitable controller having any suitable functionality with respect to any suitable device and any suitable touch sensor.

Controller 12 may be one or more integrated circuits (ICs)—such as for example general-purpose microprocessors, microcontrollers, programmable logic devices (PLDs) or arrays (PLAs), application-specific ICs (ASICs)—on a flexible printed circuit (FPC) bonded to the substrate of touch sensor 10, as described below. Controller 12 may include a processor unit, a drive unit, a sense unit, and a storage unit. The drive unit may supply drive signals to the drive electrodes of touch sensor 10. The sense unit may sense charge at the capacitive nodes of touch sensor 10 and provide measurement signals to the processor unit representing capacitances at the capacitive nodes. The processor unit may control the supply of drive signals to the drive electrodes by the drive unit and process measurement signals from the sense unit to detect and process the presence and location of a touch or proximity input within the touch-sensitive area(s) of touch sensor 10. The processor unit may also track changes in the position of a touch or proximity input within the touch-sensitive area(s) of touch sensor 10. The storage unit may store programming for execution by the processor unit, including programming for controlling the drive unit to supply drive signals to the drive electrodes, programming for processing measurement signals from the sense unit, and other suitable programming, where appropriate. Although this disclosure describes a particular controller having a particular implementation with particular components, this disclosure contemplates any suitable controller having any suitable implementation with any suitable components.

Tracks 14 of conductive material disposed on the substrate of touch sensor 10 may couple the drive or sense electrodes of touch sensor 10 to connection pads 16, also disposed on the substrate of touch sensor 10. As described below, connection pads 16 facilitate coupling of tracks 14 to controller 12. Tracks 14 may extend into or around (e.g. at the edges of) the touch-sensitive area(s) of touch sensor 10. Particular tracks 14 may provide drive connections for coupling controller 12 to drive electrodes of touch sensor 10, through which the drive unit of controller 12 may supply drive signals to the drive electrodes. Other tracks 14 may provide sense connections for coupling controller 12 to sense electrodes of touch sensor 10, through which the sense unit of controller 12 may sense charge at the capacitive nodes of touch sensor 10. Tracks 14 may be made of fine lines of metal or other conductive material. As an example and not by way of limitation, the conductive material of tracks 14 may be copper or copper-based and have a width of approximately 100 microns (μm) or less. As another example, the conductive material of tracks 14 may be silver or silver-based and have a width of approximately 100 μm or less. In particular embodiments, tracks 14 may be made of ITO in whole or in part, in addition or as an alternative to fine lines of metal or other conductive material. Although this disclosure describes particular tracks made of particular materials with particular widths, this disclosure contemplates any suitable tracks made of any suitable materials with any suitable widths. In addition to tracks 14, touch sensor 10 may include one or more ground lines terminating at a ground connector (which may be a connection pad 16) at an edge of the substrate of touch sensor 10 (similar to tracks 14).

Connection pads 16 may be located along one or more edges of the substrate, outside the touch-sensitive area(s) of touch sensor 10. As described above, touch-sensor controller 12 may be on an FPC. Connection pads 16 may be made of the same material as tracks 14 and may be bonded to the FPC using an anisotropic conductive film (ACF). Connection 18 may include conductive lines on the FPC coupling touch-sensor controller 12 to connection pads 16, in turn coupling touch-sensor controller 12 to tracks 14 and to the drive or sense electrodes of touch sensor 10. In another embodiment, connection pads 16 may be connected to an electro-mechanical connector (such as a zero insertion force wire-to-board connector); in this embodiment, connection 18 may not need to include a FPC. This disclosure contemplates any suitable connection 18 between touch-sensor controller 12 and touch sensor 10.

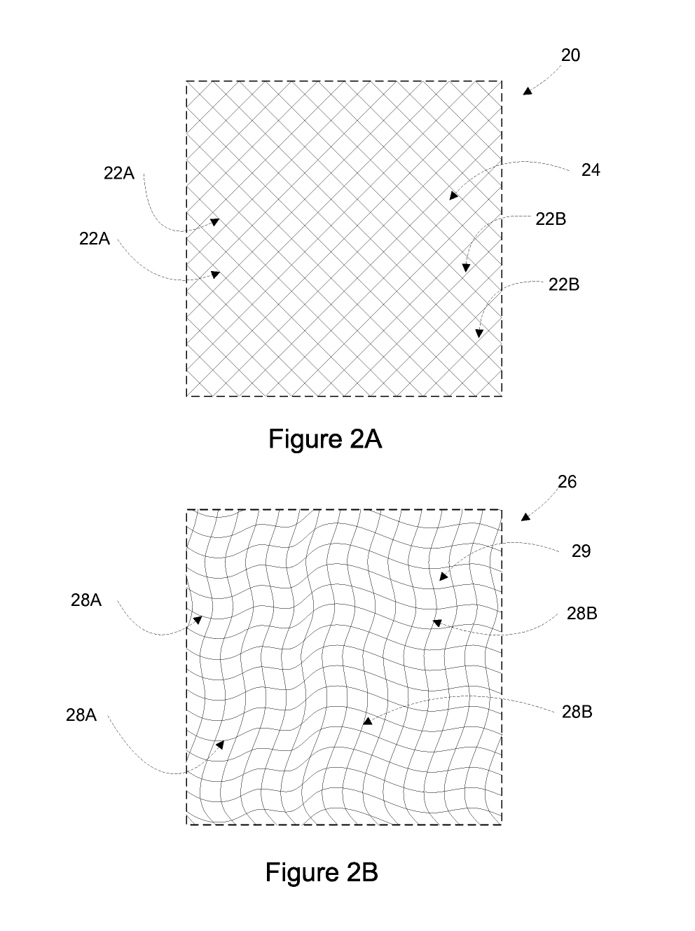

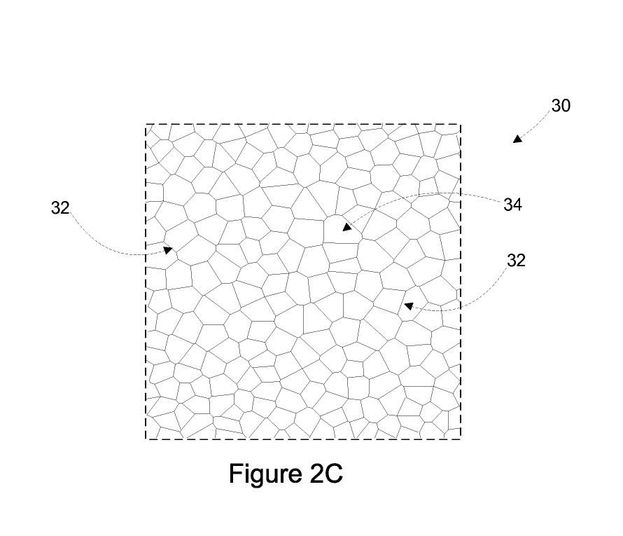

FIGS. 2A-2C illustrate example mesh patterns of a touch-sensitive layer. One or more cuts in the example mesh patterns of FIGS. 2A-2C may (at least in part) form one or more shapes (e.g. electrode or fills) of the touch sensor, and the area of the shape may (at least in part) be bounded by those cuts. The example meshes mesh patterns of FIGS. 2A-2C may be made from fine lines of metal (e.g., gold, aluminum, copper, silver, or gold-, aluminum-, copper- or silver-based material or carbon nanotubes) or other conductive material. In the example of FIG. 2A, an example mesh pattern 20 may be formed from substantially straight lines 22A-B of conductive material. Mesh pattern 20 may be formed using two sets 22A-B of substantially parallel lines of conductive material with orientation shifted by approximately 90°. The sets 22A-B of conductive lines may have substantially orthogonal intersections that form an array of diamond-shaped mesh cells 24 in mesh pattern 20.

In the example of FIG. 2B, mesh pattern 26 may be formed from two sets of substantially non-linear conductive lines 28A-B with differing orientation. In particular embodiments, non-linear line 28A-B patterns may be used to avoid long linear stretches of fine metal with a repeat frequency, reducing a probability of causing interference or moiré patterns. The non-linear pattern of the conductive lines 28A-B of mesh pattern 26 may disperse and hence reduce the visibility of reflections from conductive lines 28A-B when illuminated by incident light. As an example and not by way of limitation, each of conductive lines 28A-B of mesh pattern 26 may have a substantially sinusoidal shape. The sets 28A-28B of substantially non-linear conductive lines may have substantially non-orthogonal intersections that form an array of mesh cells 29 in mesh pattern 26. Although this disclosure describes or illustrates particular conductive lines having a particular type of path, this disclosure contemplates conductive lines following any variation in line direction or path from a straight line, including, but not limited to, wavy lines or zig-zag lines.

In the example of FIG. 2C, mesh pattern 30 may be made from randomized micro-features. Substantially randomized conductive line 32 patterns may to avoid stretches of fine metal with a repeat frequency, reducing a probability of causing interference or moiré patterns. In particular embodiments, mesh pattern 30 substantially embodies a Voronoi diagram, with notional seeds (not shown) corresponding to Voronoi sites within mesh cells 34 corresponding to Voronoi cells. As an example and not by way of limitation, every point along each conductive line 32 may be substantially equidistant from its two closest notional seeds. The notional seeds do not correspond to any material (conductive or otherwise) in the touch sensor and the notional seeds serve to determine the randomized arrangement of conductive lines 32. Moreover, randomized micro-features of mesh pattern 30 may not substantially repeat with respect to an orientation of the touch sensor (such as horizontal, vertical, or angled).

Although this disclosure describes or illustrates particular mesh patterns (e.g. 20, 26, and 30), this disclosure contemplates any suitable mesh pattern formed using any suitable conductive material having any suitable configuration. Fine lines (e.g., 22A or 32) of conductive mesh patterns (e.g. 20, 26, and 30) may occupy the surface area of a shape in a hatched, mesh, or other suitable pattern. As an example and not by way of limitation, the fine lines (e.g. 22A or 32) of conductive material may have a total line density of less than approximately 10% of a surface area. Thus, the contribution of the conductive lines to the attenuation of light through mesh pattern (e.g. 20, 26, and 30) may be within a range of approximately 1 to approximately 10%. Accordingly, although conductive lines (e.g. 22A or 32) may be opaque, the combined optical transmittance of electrodes formed using mesh pattern (e.g. 20, 26, and 30) may be approximately 90% or higher, ignoring a reduction in transmittance due to other factors such as the substrate material.

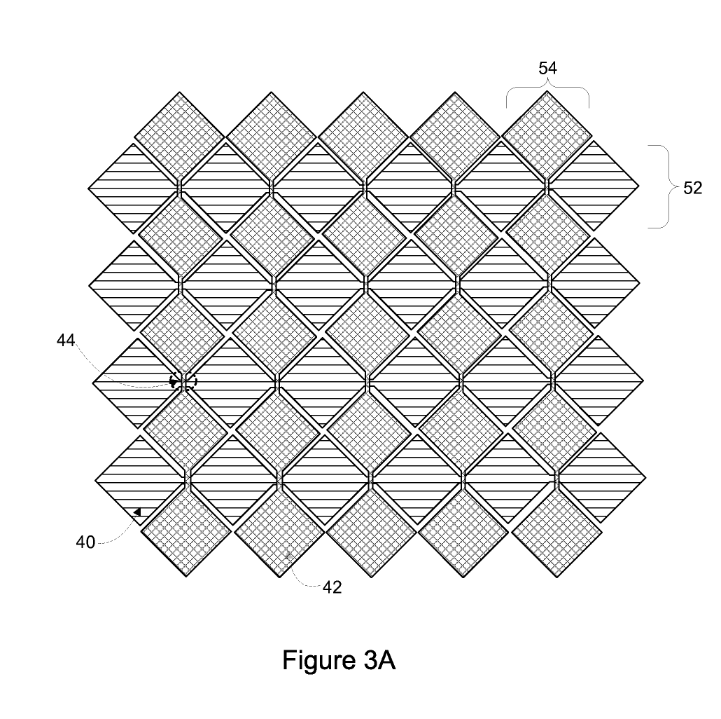

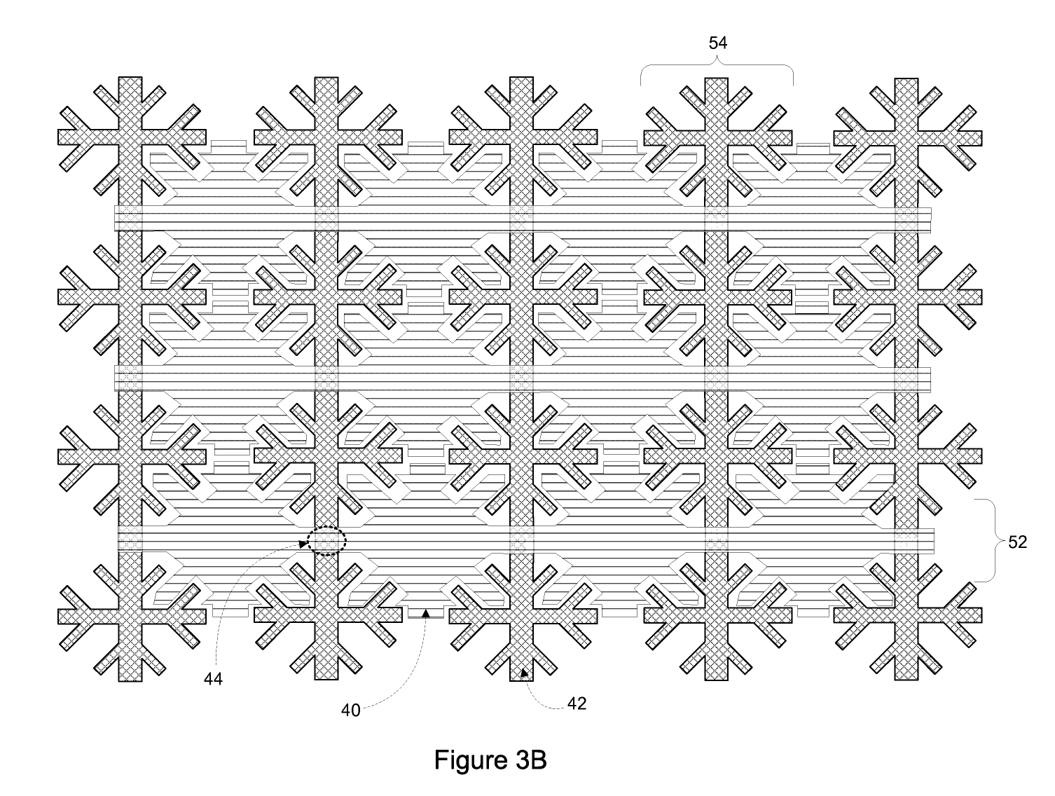

FIG. 3A illustrates a plan view of a diamond electrode pattern with crossovers. In the example of FIG. 3A, one or more electrodes 52 are formed from two or more conductive regions 40 interconnected in a first direction. One or more electrodes 54 are formed from two or more conductive regions 42 interconnected in a second direction that is substantially perpendicular to the first direction. Each electrode, e.g. 52, is separated from adjacent electrodes, e.g. 52, oriented in the same direction by a gap in the conductive material. In particular embodiments, electrodes 52 with conductive regions 40 interconnected in the first direction may function as drive electrodes and electrodes 54 with conductive regions 42 interconnected in the second direction may function as sense electrodes. Although this disclosure describes particular electrodes having a particular function, this disclosure contemplates any suitable electrodes having any suitable function.

In particular embodiments, electrodes 52 and 54 may be formed using a single layer of conductive material on the same plane, i.e. coplanar. As an example and not by way of limitation, electrodes 52 and 54 may be formed using a conductive mesh of lines of conductive material, as described above. Moreover, the shape of conductive regions 40 and 42 may be made using cuts in the conductive mesh. As an example and not by way of limitation, cuts in the conductive mesh may be used to formed substantially square-shaped conductive regions 40 and 42. At intersections 44 between electrodes 52 oriented in the first direction and electrodes 54 oriented in the second direction, the conductive material of electrode 54 spans the conductive material of electrode 52 using a conductive crossover. As an example and not by way of limitation, the conductive crossovers include conductive material that contacts a portion of two adjacent conductive regions 40. The conductive material of the conductive crossovers may be separated from the conductive material of conductive region 42 by a dielectric or non-conducting material as described below. Although this disclosure describes or illustrates conductive crossovers bridging particular electrodes, this disclosure contemplates conductive crossovers bridging any suitable electrodes.

FIG. 3B illustrates a plan view of a snowflake electrode pattern with crossovers. In the example of FIG. 3B, one or more electrodes 52 are formed from two or more conductive regions 40 interconnected in a first direction. One or more electrodes 54 formed from two or more conductive regions 42 interconnected in a second direction that is substantially perpendicular to the first direction. As described above, each electrode, e.g. 52, is separated from adjacent electrodes, e.g. 52, oriented in the same direction by a gap in the conductive material. In particular embodiments, electrodes 52 formed from conductive regions 40 interconnected in the first direction may function as drive electrodes and electrodes 54 formed from conductive regions 42 interconnected in the second direction may function as sense electrodes. Although this disclosure describes particular electrodes having a particular function, this disclosure contemplates any suitable electrodes having any suitable function.

As described above, electrodes 52 and 54 may be formed using a single layer of conductive material, i.e. coplanar. As an example and not by way of limitation, electrodes 52 and 54 may be formed using cuts in a conductive mesh of lines of conductive material. Moreover, cuts in the conductive mesh may be used to form substantially diamond-shaped conductive regions 40 and conductive regions 42 with a substantially rectangular-shaped portion and a cross portion substantially perpendicular to the substantially rectangular-shaped portion. In particular embodiments, cuts in the conductive mesh are used to form projections extending from each side of diamond-shaped-conductive region 40. Moreover, cuts in the conductive mesh are used to form projections extending from the substantially rectangular-shaped and cross portion of conductive region 42. The combination of electrodes 40 and 42 with projections may be referred to as interdigitated or interleaved projections that increase the adjacent perimeters of electrodes 40 and 42. Although this disclosure describes or illustrates electrodes formed from particularly-shaped-conductive regions, this disclosure contemplates any suitably-shape-conductive regions, including, but not limited to, squares or rectangles.

As described above, the conductive material of electrode 54 spans the conductive material of electrode 52 at intersections 44 between electrodes 52 and electrodes 54 using a conductive crossover. As an example and not by way of limitation, the conductive crossovers are conductive material that contacts a portion of two adjacent conductive regions 40. The conductive material of the conductive crossovers may be separated from the conductive material of electrodes 54 by a dielectric or non-conducting material, as described below. Although this disclosure describes or illustrates conductive crossovers bridging particular electrodes, this disclosure contemplates conductive crossovers bridging any suitable electrodes.

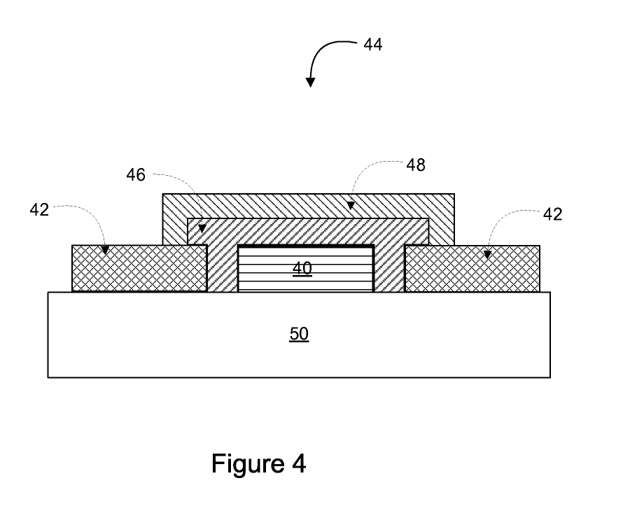

FIG. 4 illustrates a cross-sectional view of an example crossover. In the example of FIG. 4, portions of conductive region 42 spans conductive region 40 through a conductive crossover at intersection 44 of electrode 52 and electrode 54. A dielectric or non-conducting layer 46 is formed over the conductive material of conductive region 40. In particular embodiments, non-conducting layer 42 may be formed over a portion of conductive regions 42. Conductive material 48 of the crossover structure couples portions of two adjacent conductive regions 42. Dielectric layer 46 separates conductive material 48 of the crossover structure from conductive material of conductive region 40. In particular embodiments, conductive material 48 of the crossover structure is on the same side of substrate 50 as conductive regions 40 and 42. Although this disclosure describes or illustrates conductive crossovers bridging particular electrodes, this disclosure contemplates conductive crossovers bridging any suitable electrodes.

Herein, reference to a computer-readable storage medium may include a semiconductor-based or other IC (such, as for example, a field-programmable gate array (FPGA) or an ASIC), a hard disk drive (HDD), a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, another suitable computer-readable storage medium, or a suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. An apparatus comprising:
one or more drive or sense electrodes of a touch sensor, each of the electrodes comprising a plurality of conductive regions being made of a conductive mesh of lines of conductive material; and
one or more conductive crossovers that each couple two of the conductive regions of the drive electrodes to each other or couple two of the conductive regions of the sense electrodes to each other, at least a portion of each of the conductive crossovers being disposed on a plane different than a plane of the drive or sense electrodes.

2. The apparatus of claim 1, wherein one or more projections made of the conductive mesh extend from one or more of the conductive regions of the drive or sense electrodes.

3. The apparatus of claim 2, wherein one or more of the projections of the drive electrodes are interleaved with one or more of the projections of the sense electrodes.

4. The apparatus of claim 1, wherein the drive and sense electrodes comprise one or more substantially square-shaped conductive regions.

5. The apparatus of claim 1, wherein the drive and sense electrodes are on a same plane with respect to each other.

6. The apparatus of claim 1, further comprising dielectric material separating each of the conductive crossovers from conductive material of an adjacent electrode.

7. The apparatus of claim 6, wherein the dielectric material substantially electrically isolates the conductive crossovers of the sense electrodes from conductive regions of the drive electrodes or the conductive crossovers of the drive electrodes from conductive regions of the sense electrodes.

8. The apparatus of claim 1, wherein the conductive material comprises gold, aluminum, copper, silver, gold-based, aluminum-based, silver-based, or copper-based, or carbon nanotubes.

9. The apparatus of claim 1, wherein drive and sense electrodes are substantially transparent and the conductive material is optically opaque.

10. The apparatus of claim 1, wherein the conductive crossovers are disposed on a same side of a substrate as the drive and sense electrodes.

11. A device comprising:
a touch sensor comprising:
one or more drive or sense electrodes of a touch sensor, each of the electrodes comprising a plurality of conductive regions being made of a conductive mesh of lines of conductive material; and
one or more conductive crossovers that each couple two of the conductive regions of the drive electrodes to each other or couple two of the conductive regions of the sense electrodes to each other, at least a portion of each of the conductive crossovers being disposed on a plane different than a plane of the drive or sense electrodes; and
a computer-readable non-transitory storage medium embodying logic that is configured when executed to control the touch sensor.

12. The device of claim 11, wherein one or more projections made of the conductive mesh extend from one or more of the conductive regions of the drive or sense electrodes.

13. The device of claim 12, wherein one or more of the projections of the drive electrodes are interleaved with one or more of the projections of the sense electrodes.

14. The device of claim 11, wherein the drive and sense electrodes comprise one or more substantially square-shaped conductive regions.

15. The device of claim 11, wherein the drive and sense electrodes on a same plane with respect to each other.

16. The device of claim 11, further comprising dielectric material separating each of the conductive crossovers from conductive material of an adjacent electrode.

17. The device of claim 16, wherein the dielectric material substantially electrically isolates the conductive crossovers of the sense electrodes from conductive regions of the drive electrodes or the conductive crossovers of the drive electrodes from conductive regions of the sense electrodes.

18. The device of claim 11, wherein the conductive material comprises gold, aluminum, copper, silver, gold-based, aluminum-based, silver-based, or copper-based, or carbon nanotubes.

19. The device of claim 11, wherein drive and sense electrodes are substantially transparent and the conductive material is optically opaque.

20. The device of claim 11, wherein the conductive crossovers are disposed on a same side of a substrate as the drive and sense electrodes.
